(19) United States
(12) Patent Application Publication
(10) Pub. No.: US 2026/0282249 A1
(43) Pub. Date: Sep. 17, 2026

(54) VARIABLE FLOW BAROMETRIC VENT SYSTEM

(71) Applicant: Apple Inc., Cupertino, CA (US)

(72) Inventors: Ankur Agrawal, Santa Clara, CA (US); Michael J Glickman, Mountain View, CA (US); Seow Yuen Yee, Mountain View, CA (US); Tyler S Bushnell, San Francisco, CA (US)

(21) Appl. No.: 19/078,161

(22) Filed: Mar. 12, 2025

(51) Int. Cl. H05K 5/02

(52) U.S. Cl. CPC H05K 5/0215

(57) ABSTRACT

An internal cavity of an electronic device can be in fluid communication with an external environment. The device can include a sensor and a barometric vent. The vent can include a first membrane including a first and second portion having a first and second permeability with the second permeability being higher than the first, and a second membrane including a third portion having a third permeability higher than the first and a fourth portion aligned with the second portion, the fourth portion having a fourth permeability less than the second. The device can include an actuator electrically coupled to the sensor and configured to selectively actuate the vent between an open and closed position based on a trigger from the sensor. The barometric vent can include an open position with the first and second membranes separated, and a closed position with contact between the first and second membranes.

### FIELD

The present disclosure relates generally to barometric vents of an electronic device. More particularly, the present disclosure relates to variable flow barometric vent systems.

### BACKGROUND

In electronic devices, an internal cavity of a device enclosure can have a nominal internal air pressure. If air pressure within the internal cavity cannot be equalized with the electronic device's external environment, the electronic device or its constituent components can warp, break, or cease functioning. Accordingly, electronic devices expected to be subjected to high-or low-pressure environments can incorporate a barometric vent. In some cases, barometric vents can be a path for ingress of foreign contaminants, including liquid contaminants. When the internal components of the electronic device are exposed to contaminants, especially liquid contaminants such as water, those internal components, or the electronic device as a whole, can malfunction or cease functioning entirely. Therefore, what is needed in the art are barometric vents that can regulate pressures and reduce or eliminate contaminant ingress.

### SUMMARY

In at least one example of the present disclosure, an electronic device can include a housing defining an internal cavity and a port. In some examples, the internal cavity can be in fluid communication with an external environment through the port. In some examples, the electronic device also includes an environmental sensor in the internal cavity and a barometric vent disposed at the port between the environmental sensor and the housing. In some examples, the barometric vent can include a first membrane and a second membrane. In some examples, the first membrane can include a first portion having a first permeability and a second portion having a second permeability higher than the first permeability. In some examples, the second membrane can include a third portion having a third permeability higher than the first permeability and a fourth portion aligned with the second portion, the fourth portion having a fourth permeability less than the second permeability. In some examples, the electronic device can further include an actuator electrically coupled to the environmental sensor and configured to selectively actuate the barometric vent between an open position and a closed position based on a trigger from the environmental sensor. In some examples of the actuator, the open position can include the first membrane being separated from the second membrane and the closed position can include the fourth portion being in contact with the first membrane.

In some examples, the actuator of the electronic device can also include an electromagnet. In some examples of the electronic device, the actuator can include a shape memory alloy. In some examples of the electronic device, the actuator can be configured to selectively actuate the barometric vent using electrostatic actuation. In some examples, the actuator of the electronic device can include a piezoelectric actuator. In some examples, the electronic device can further include a retention spring coupling the actuator to at least one of the first membrane or the second membrane. In some examples of the electronic device, the first permeability and the fourth permeability are less than about 50 SCCM per cm\hat{ }2 of membrane active area. In some examples, the environmental sensor of the electronic device can also include at least one of a moisture sensor, a pressure sensor, or a temperature sensor. In some examples, the actuator of the electronic device can also be selectively triggered by a user.

In at least one example of the present disclosure, a barometric vent for a portable electronic device can include a first membrane layer and a second membrane layer adjacent to the first membrane layer. In some examples, the first membrane layer can include a first low-flow membrane having a first permeability and at least one of a hole defined by the first low-flow membrane or a first high-flow membrane having a second permeability. In some examples, the second membrane layer can include a second high-flow membrane having a third permeability and a second low-flow membrane having a fourth permeability. In some examples, the second membrane layer can include the second low-flow membrane positioned in line with at least one of the hole or the first high-flow membrane. In some examples, the barometric vent can also include an actuator configured to selectively actuate at least one of the first membrane layer or the second membrane layer to enable a first flow rate or a second flow rate through the barometric vent.

In some examples, the barometric vent can include the first low-flow membrane positioned in line with the second high-flow membrane and can include at least one of the hole or the first high-flow membrane positioned in line with the second low-flow membrane. In some examples, the barometric vent can further include a third membrane layer, the third membrane layer can include a third high-flow membrane and a third low-flow membrane. In some examples, the barometric vent can include the third low-flow membrane positioned in line with the second high-flow membrane. In some examples of the barometric vent, the first membrane layer can further include a first membrane section and a second membrane section adjacent to the first membrane section. In some examples, the first membrane section includes at least one of the hole or the first-high-flow membrane and the second low-flow membrane. In some examples, the second membrane section can include at least one of the hole or the first high-flow membrane, and the second low-flow membrane. In some examples, the first membrane layer can include at least one of the hole or the first high-flow membrane of the first membrane section in line with the second low-flow membrane of the second membrane section and the second low-flow membrane of the first membrane section in line with the at least one of the hole or the first high-flow membrane. In some examples, the barometric vent can include the actuator being configured to selectively actuate a position of at least one of the first membrane layer or the second membrane layer using at least one of electromagnetism, temperature dependency, piezoelectric actuation, or electrostatics.

In at least one example of the present disclosure, a barometric vent can include a membrane having a first volume and a second volume, and an actuator configured to switch the membrane between the first volume and the second volume. In some examples, the barometric vent can include the first volume corresponding to a first permeability and a second volume corresponding to a second permeability different than the first permeability. In some examples, the barometric vent can include at least one of the first permeability or the second permeability are less than about 50 SCCM per cm\hat{ }2 of membrane active area. In some examples of the barometric vent, the membrane can further include a sponge-like material. In some examples of the barometric vent, the actuator can be configured to selectively actuate the barometric vent using at least one of electromagnetism, temperature dependency, or electrostatic actuation. In some examples, the barometric vent can further include an environmental sensor electrically coupled to the actuator. In some examples of the barometric vent, the actuator can be configured to be triggered to switch the membrane between the first volume and the second volume by at least one of the environmental sensor or a user.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 shows a front perspective view of an example of an electronic device having a barometric vent;

FIG. 2A shows a cross-sectional view of an example of a barometric vent in an open position;

FIG. 2B shows a cross-sectional view of an example of a barometric vent in a closed position;

FIG. 3A shows a cross-sectional view of an example of a barometric vent in an open position;

FIG. 3B shows a cross-sectional view of an example of a barometric vent in a closed position;

FIG. 4A shows a cross-sectional view of an example of a barometric vent in an open position;

FIG. 4B shows a cross-sectional view of an example of a barometric vent in a closed position;

FIG. 5A shows a cross-sectional view of an example of a barometric vent in an open position;

FIG. 5B shows a cross-sectional view of an example of a barometric vent in a closed position;

FIG. 6A shows a cross-sectional view of an example of a barometric vent in an open position;

FIG. 6B shows a cross-sectional view of an example of a barometric vent in a closed position;

FIG. 7A shows a top view of an example of a membrane layer;

FIG. 7B shows a top view of an example of a membrane layer; and

FIG. 7C shows a top view of an example of a membrane layer.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

The following disclosure relates to barometric vents of electronic devices. A barometric vent facilitates equilibrium between an internal cavity of the electronic device and the external environment. The barometric vent allows fluid, typically air, to travel between the internal cavity of the electronic device and the device's external environment. Many barometric vents, however, are not selective and cannot control the flow rate of the fluids permitted to travel between the internal cavity and the external environment. Accordingly, traditional barometric vents can permit the flow of unwanted fluids, such as water and other liquids present in the external environment that can contaminate the internal cavity of the electronic device. These unwanted fluids and contaminants can cause damage to the internal components of the electronic device causing the electronic device to malfunction or cease working. The devices, systems, and methods of the present disclosure include barometric vents that selectively actuate between an open and closed position to allow fluid to enter and equalize the pressure of an electronic device in appropriate external environments while preventing unwanted fluids such as liquids from entering the internal cavity in undesirable environments, such as those environments where a certain level of moisture is detected.

In some examples, an electronic device can include a housing which can define an internal cavity and a port. In some examples, the electronic device can also include a barometric vent which can be disposed at the port between the environmental sensor and the housing, separating the internal cavity from the electronic device's external environment. In some examples, the barometric vent can include an actuator, a first membrane, and a second membrane. In some examples, the first membrane can include a first portion and second portion with a first permeability and second permeability, respectively. In some examples, the second permeability can be higher than the first permeability. Similarly, in some examples the second membrane can include a third portion and fourth portion with a third permeability and fourth permeability, respectively. In some examples, the fourth permeability can be lower than the second permeability. Additionally, the third permeability can be higher than the first permeability. Fluids flow with less resistance through higher permeabilities. Thus, in some examples, fluid can flow with less resistance through the second portion and third portion than the first portion or fourth portion. Selective alignment of the varying portions with differing permeability can provide selective actuation and predictable fluid flow in varying environments.

In some examples, the fourth portion of the second membrane is aligned with the second portion of the first membrane. The actuator can be electrically coupled to an environmental sensor and can be configured to selectively actuate the barometric vent between an open and closed position based on a trigger from the environmental sensor. For example, the actuator can be configured to actuate the barometric vent from an open position to a closed position when the environmental sensor, such as a moisture sensor, senses the presence of a predetermined amount of water or other liquid.

In some examples when the barometric vent is in the open position, the first and second membranes are separated, allowing air to flow with less resistance through the higher permeability portions of each membrane. In some examples, when the barometric vent is in a closed position the membranes are in contact with one another and the fluids cannot flow with as little resistance from the external environment of the electronic device to the internal cavity because the higher permeability portions of each membrane are in contact with the lower permeability portions of the adjacent membrane, reducing the overall permeability of the barometric vent. For example, in the closed position of the barometric vent, the second portion of the first membrane is in contact with the fourth portion of the second membrane and the fourth portion has a lower permeability than the second portion.

In some examples, a barometric vent for a portable device can include a first membrane layer, a second membrane layer adjacent to the first membrane layer, and an actuator configured to selectively actuate the first membrane layer or the second membrane layer to enable a first flow rate or a second flow rate through the barometric vent, with one flow rate being greater than the other. In some examples, the first membrane layer can have a low-flow membrane with a first permeability and at least one of a hole defined by the first membrane or a first high-flow membrane having a second permeability. Similarly, in some examples the second membrane layer can have a second high-flow membrane having a third permeability and a second low-flow membrane having a fourth permeability. In some examples, the second low-flow membrane can be positioned in line with the at least one of the hole or the first high-flow membrane. In such examples, the flow rate of the fluid through the barometric vent is higher when the adjacent membrane layers are separated and the flow rate of the fluid through the barometric vent is lower when the adjacent membrane layers are closer together. In this way, the flow rate of the fluid through the barometric vent is lowest when the membrane layers are in contact.

In some examples, the barometric vent includes a membrane coupled to an actuator. In some examples, the membrane can have a first and second volume where each volume corresponds to a different permeability. In some examples, the first volume corresponds to a first permeability and the second volume corresponds to a second permeability. In some examples, the actuator can be configured to switch the membrane between the first volume and the second volume, resulting in a change of the permeability of the barometric vent.

These variable-flow barometric vents, and other examples of barometric vents described herein, can regulate flow in-and-out of the device to equalize pressure when desired but also selectively close when placed in undesirable environments, such as high-moisture environments, to protect from liquid ingress.

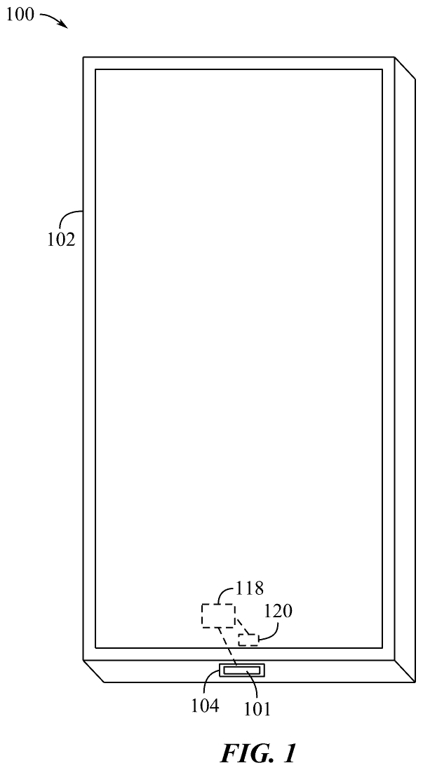

These and other embodiments are discussed below with reference to FIG. 1-7B. However, those skilled in the art will readily appreciate that the detailed description given herein with respect to these figures is for explanatory purposes only and should not be construed as limiting. Furthermore, as used herein, a system, a method, an article, a component, a feature, or a sub-feature including at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option).

FIG. 1 shows a front view of an example of an electronic device 100 having a housing 102. In some examples, the electronic device can be a smart phone, a tablet, a watch, or a head mountable device. The housing 102 can define an internal cavity within the electronic device 100 and a port 104. In some examples, the internal cavity is in fluid communication with an external environment through the port 104. In some examples, the electronic device 100 can contain an environmental sensor 120 in the internal cavity and a barometric vent 101 disposed at the port 104 between the environmental sensor and the housing 102. In some examples, the environmental sensor 120 can include a moisture sensor, a temperature sensor, a pressure sensor, or other sensor indicating a change in an external environment that could be harmful to the internal components of the electronic device.

In some examples, the barometric vent 101 can include a controller 118 electrically coupled to the environmental sensor 120, as shown by the dashed lines connecting the controller 118 and the environmental sensor 120, and to an actuator. The controller 118 can be configured to control the actuator to selectively actuate the barometric vent 101 between an open position and a closed position based on a trigger from the environmental sensor 120. The electrical connections are shown through dotted lines connecting the barometric vent 101, controller 118, and environmental sensor 120. In some examples, when the environmental sensor 120 detects a predetermined feature the environmental sensor 120 is configured to detect, it sends an electrical signal to the controller 120. The controller 120 then controls the actuator which actuates the barometric vent 101 to selectively open or close, or otherwise change the configuration and permeability of the barometric vent 101. For example, when an environmental sensor 120, such as a moisture sensor, detects a predetermine level of moisture, the controller 120 can control the actuator to actuate the barometric vent 101 to move into the closed or flow restricted position.

The barometric vent, including the controller 118 and the environmental sensor 120 noted above, are not shown in detail FIG. 1, as they are disposed in the internal cavity of the electronic device 101 as represented by the dashed boxes, but are shown in other figures and described in more detail below. The electronic device 100 can be a portable device configured to be used in different environments, including wet environments, for example using a phone outside in the rain or wearing an electronic watch while swimming. The barometric vent 101 at the port 104 can be controlled to equalize pressure between an inner volume of the electronic device 100 and the external environment by allowing air to flow through the port 104 when the external environment does not pose a threat of liquid ingress through the port 104. The barometric vent 101 can also be controlled to close-off liquid ingress when the external environment is too wet, for example when exposed to rain or sweat or when submerged in water or other liquids. In some examples described herein, the barometric vents 101 can be variable-flow vents configured to increase or decrease airflow and/or liquid ingress based on the detected environment.

Any of the features, components, and/or parts, including the arrangements and configurations thereof shown in FIG. 1 can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 1.

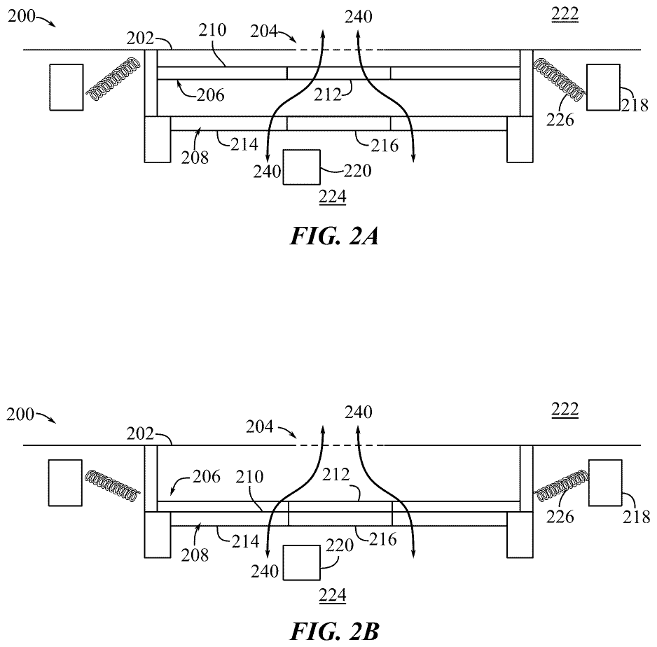

FIG. 2A-2B show cross-sectional views of an example of a barometric vent 200 disposed at the port 204 of the electronic device 100 in an open position and a closed position, respectively. In some examples, the barometric vent 200 can include a first membrane 206 and a second membrane 208. In some examples, the first membrane 206 can include a first portion 210 having a first permeability and a second portion 212 having a second permeability, the second permeability being higher than the first permeability. In some examples, the second portion 212 with the second permeability permits a fluid to flow with less resistance through the second portion 212 than the first portion 210 having the lower first permeability. In some examples, the second membrane 208 can include a third portion 214 having a third permeability and a fourth portion 216 having a fourth permeability. In some examples, the third permeability is higher than the first permeability. In some examples, the fourth permeability is higher than the second permeability.

In some examples, the barometric vent 200 includes an actuator 218. In some examples, the actuator 218 can be configured to selectively actuate the barometric vent 200 between an open position, an example of which is shown in FIG. 2A, and a closed position, an example of which is shown in FIG. 2B. In some examples, the open position shown in FIG. 2A includes separation between the first membrane 206 and the second membrane 208. The separation between the first membrane 206 and the second membrane 208 can allow a fluid to flow in the path of least resistance between the external environment 222 and the internal cavity 224 of the electronic device 100 through the port 204 defined by the housing 202 and through the higher permeability portion, the second portion 212, of the first membrane 206, to the higher permeability portion, the third portion 214, of the second membrane 208. This lowest resistance flow of fluid between the external environment 222 to the internal cavity 224 is shown by the double-sided arrows in FIG. 2A indicating a fluid flow path 240. The fluid flows more easily when the barometric vent 200 is in the open position, shown in FIG. 2A. The fluid flow is restricted when the barometric vent 200 is in the closed position, shown in FIG. 2B.

In some examples, fluid also flows through the fluid flow path 240 through the first portion 210 and the fourth portion 216, however, a higher pressure differential between the external environment 222 and the internal cavity 224 is needed for the fluid to flow through these portions relative to a pressure needed for fluid to flow through the second portion 212 and the third portion 214. This is because the second portion 212 and third portion 214 have higher permeabilities than the first portion 210 and fourth portion 216. In some examples, the first portion 210 can be positioned in line with the third portion 214. In some examples, at least one of a hole or the second portion 212 can be positioned in line with the fourth portion 216. In this way, when the membranes 206, 208 come into contact in the closed position shown in FIG. 2B, the fluid flowing through the fluid flow path 240 of the barometric vent 200 can be reduced or shut off.

In some examples, the actuator 218 is electrically coupled to an environmental sensor 220. The environmental sensor 220 can detect a feature of the external environment 222, for example the temperature, pressure, or moisture content, and can trigger the actuator 218 to actuate the barometric vent 200 between an open position, as shown in FIG. 2A, to a closed position, as shown in FIG. 2B. The environmental sensor 220 can trigger the actuator 218 by sending a signal corresponding to the detected environmental property to a controller, for example the controller 118 shown in FIG. 1, which is in electrical communication with the environmental sensor 220 and the actuator 218. The controller 118 can be configured to selectively actuate the actuator 218 based on that signal. The controller can include one or more processing and/or computing components, such as a processor, memory component, antenna, or other components for electrically communicating with and controlling the various components of the barometric vents 200 and vent systems described herein.

In some examples, the electronic device 100 can also include a retention spring 226 coupling the actuator 218 to at least one of the first membrane 206 or the second membrane 208. The retention spring 226 can assist the actuator 218 in facilitating the relative movement of at least one of the first membrane 206 or the second membrane 208 relative to one another when actuated between the open position, shown in FIG. 2A, and the closed position, shown in FIG. 2B. The spring 226 shown in FIGS. 2A and 2B, and elsewhere in the figures, is illustrated as a coil spring. This is not intended to be limiting, and other examples can include other types of springs including spring fingers, materials having spring constants configured to expand and contract with a spring force, or other types of springs and biasing members and materials. In some examples, the retention spring 226 can represent a spring constant of the material of at least one of the first membrane 206 or the second membrane 208. In some examples, the retention spring 226 can be coupled to other components of the electronic device 100, including the housing 202.

In some examples, the actuator 218 can include an electromagnet to actuate at least one of the first membrane 206 or the second membrane 208 between the open position, shown in FIG. 2A, and the closed position, shown in FIG. 2B. When the actuator 218 receives a signal from the environmental sensor 220 to actuate the barometric vent 200 between the open and closed positions, an electrical charge may be introduced creating a magnetic field. This magnetic field can cause at least one of the first membrane 206 or the second membrane 208 to change positions creating space between the first membrane 206 and the second membrane 208 to place the barometric vent 200 in the open position, shown in FIG. 2A, or closing the space between the first membrane 206 and the second membrane 208 and causing the membranes to come into contact with each other to place the barometric vent 200 in the closed position, shown in FIG. 2B.

Any of the features, components, and/or parts, including the arrangements and configurations thereof shown in FIG. 2A-2B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 2A-2B.

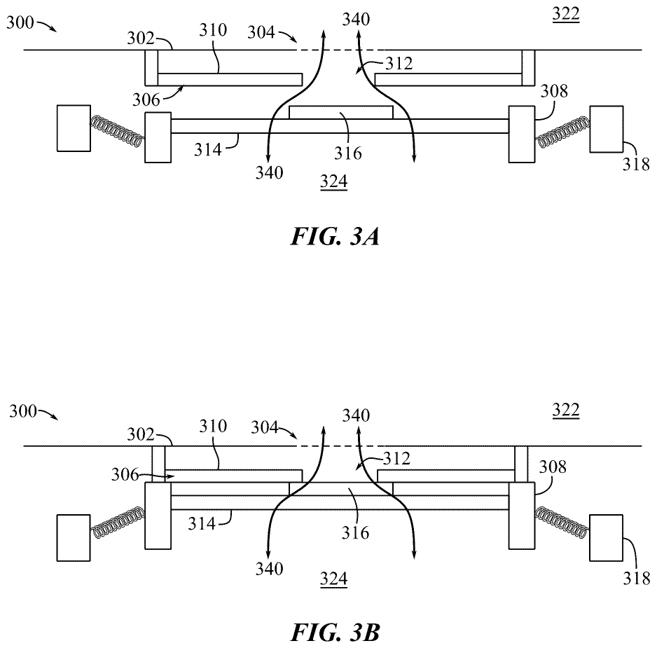

FIGS. 3A and 3B show cross-sectional views of an example of a barometric vent 300 disposed at the port 304 of the electronic device 100 in an open position and a closed position, respectively. In some examples, the barometric vent 300 includes a first membrane layer 306, a second membrane layer 308 positioned to be adjacent to the first membrane layer 306, and an actuator 318. In some examples, the first membrane layer 306 can include a first low-flow membrane 310 having a first permeability and at least one of a hole 312 or orifice defined by the first membrane 310, an example of which is shown in FIGS. 3A and 3B, or a first high-flow membrane, similar to that shown in FIGS. 2A and 2B (212), having a second permeability. In some examples, the second membrane layer 308 can include a second high-flow membrane 314 having a third permeability and a second low-flow membrane 316 having a fourth permeability. In some examples, the second high-flow membrane 314 is positioned in line with at least one of the hole 312 or the first high flow membrane.

In some examples, the actuator 318 can be configured to selectively actuate at least one of the first membrane layer 306 or the second membrane layer 308 to enable a first flow rate or a second flow rate through the barometric vent 300. The fluid flows more easily, resulting in a higher flow rate, when the barometric vent 300 is in the open position, shown in FIG. 3A, and the fluid flow is restricted, resulting in a lower flow rate, when the barometric vent 300 is in the closed position, shown in FIG. 3B. In some examples, the actuator 318 is configured to selectively actuate the barometric vent 300 using electrostatic actuation. For example, when an environmental sensor 320 detects a change in the external environment 222, the actuator may flip an electrical charge within at least one of the first membrane layer 306 or the second membrane layer 308 causing the membrane layers to move the barometric vent 300 between the open and closed positions, shown in FIG. 3A and FIG. 3B, respectively. For example, if the electrical charges within the membrane layers 306, 308 are triggered by the actuator 318 to attract each other, the membrane layers 306, 308 can move together into the closed position, shown in FIG. 3B. However, if the charges within the membrane layers 306, 308 are triggered by the actuator 318 to repel each other, the membrane layers 306, 308 will move away from each other causing separation between the layers 306, 308 and creating the open position shown in FIG. 3A.

The double-sided arrows in FIG. 3A, indicating a fluid flow path 340, show an example of fluid traveling in the first flow rate in the path of least resistance between the external environment 322 to the internal cavity 324 of the electronic device 100. More specifically, in some examples, fluid can flow from the external environment 322 to the internal cavity 324 by flowing through the port 304 defined by the housing 302, through the hole 312 or first high-flow membrane of the first membrane layer 306 and then through the second high-flow membrane 314 of the second membrane layer 308.

FIG. 3B shows an example of fluid flowing in the second flow rate, with increased resistance between the first membrane layer 306 and the second membrane layer 308 since the low-flow membranes 316 and 310 overlap with at least one of the hole 312 or the high-flow membranes 314. In some examples, this configuration can reduce or prevent the fluid from flowing through the holes and/or high-flow membranes 312 and 314.

Any of the features, components, and/or parts, including the arrangements and configurations thereof shown in FIG. 3A-3B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 3A-3B.

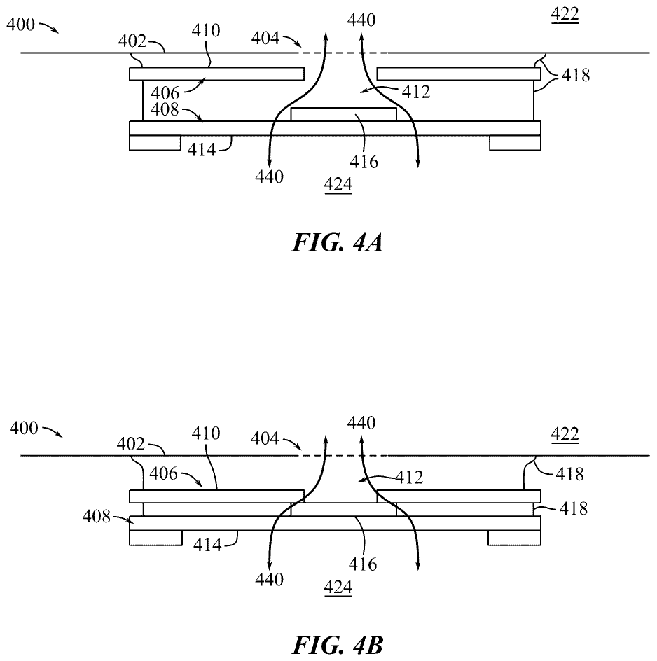

FIG. 4A-4B show cross-sectional views of an example of a barometric vent 400 disposed at the port 404 of the electronic device 100 in an open position and a closed position, respectively. In some examples, the barometric vent 400 includes a first membrane layer 406, a second membrane layer 408 adjacent to the first membrane layer 406, and an actuator 418. In some examples, the first membrane layer 406 can include a first low-flow membrane 410 having a first permeability and at least one of a hole 412 defined by the first membrane or a first high-flow membrane (similar to 212, the membrane shown in FIGS. 2A and 2B) having a second permeability. In some examples, the second membrane layer 408 can include a second high-flow membrane 414 having a third permeability and a second low-flow membrane 416 having a fourth permeability. In some examples, the second low-flow membrane 414 is positioned in line with at least one of the hole 412 or the second high-flow membrane.

In some examples, the actuator 418 can be configured to selectively actuate at least one of the first membrane layer 406 or the second membrane layer 408 to enable a first flow rate or a second flow rate through the barometric vent 400. FIG. 4A shows an example of the barometric vent 400 in an open position. The double-sided arrows in FIG. 4A show an example of fluid and sound signals traveling in the path 440 of least resistance between the external environment 422 to the internal cavity 424 of the electronic device 100. More specifically, in some examples, fluid and sound signals can flow between the external environment 422 to the internal cavity 424 by flowing through the port 404 defined by the housing 402, through at least one of the hole 412 or first high-flow membrane of the first membrane layer 406, the fluid and sound signals then can flow with the least resistance through the second high-flow membrane 414 of the second membrane layer 408. In some examples, the actuator 418 is configured to selectively actuate the barometric vent 400 using electrostatic actuation. In some examples, the actuator 418 can comprise a shape memory alloy enabled by lengthening or shrinking only during actuation and then relaxing to its original length after some time or after the actuation ends. In other examples, the barometric vent 400 can include a piezoelectric actuator to expand or contract a shape memory alloy to actuate the barometric vent between an open position, shown in FIG. 4A and a closed position, shown in FIG. 4B.

In some examples, actuation occurs in response to activity of a microphone 420 which can signal the actuator 418 to actuate the barometric vent 400 between an open position, shown in FIG. 4A, where the first membrane layer 406 and the second membrane layer 408 are separated and a closed position, shown in FIG. 4B, where the first membrane layer 406 and the second membrane layer 408 contact each other or are in close proximity of one another. In the open position, shown in FIG. 4A, sound signals may pass more easily through the barometric vent 400. In some examples, the barometric vent 400 can be configured to be in the open position when the microphone 420 of the electronic device 100 is in use or is enabled. FIG. 4B shows an example of fluid and sound signals flowing in the second flow rate, with increased resistance between the first membrane layer 406 and the second membrane layer 408 since the low-flow membranes 416 and 410 overlap with at least one of the hole or the high-flow membranes 412 and 414. In some examples, this configuration can reduce or prevent the fluid, as well as the sound signals, from flowing through the barometric vent 400. In some examples, reducing the fluid flow, despite reducing the flow of the sound signals, through barometric vent 400 can protect the microphone 420 and other electronic components within the internal cavity of the electronic device 100 from damage by reducing the egress of unwanted fluids such as water when the electronic device 100 does not need to capture sound signals, for example when the microphone 420 is not in use or is not enabled.

Any of the features, components, and/or parts, including the arrangements and configurations thereof shown in FIG. 4A-4B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 4A-4B.

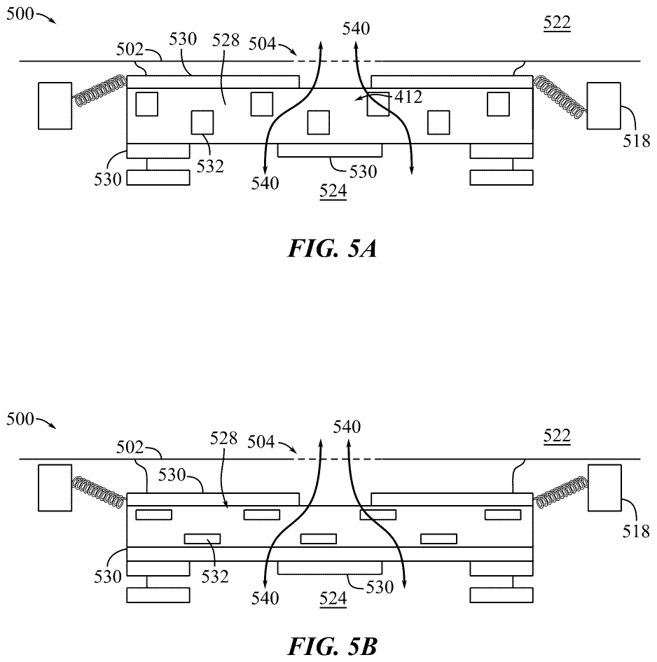

FIG. 5A-5B show cross-sectional views of an example of a barometric vent 500 disposed at the port 504 of the electronic device 100 in an open position and a closed position, respectively. In some examples, the barometric vent 500 includes a membrane 528 having a first volume, an example of which is shown in FIG. 5A, and a second volume, an example of which is shown in FIG. 5B. In some examples, the barometric vent 500 also includes an actuator 518 configured to switch the membrane 528 between the first volume, shown in FIG. 5A, and the second volume, shown in FIG. 5B after receiving a trigger from an environmental sensor 520. In some examples, the first volume corresponds to a first permeability and the second volume, corresponds to a second permeability different from the first permeability.

In some examples, a plurality of low-flow membranes 530 can be placed on the top and/or the bottom of the membrane 528 to further control the flow rate of a fluid flowing between an external environment 522 and the internal cavity 524 of the electronic device 100. Double-sided arrows in both FIGS. 5A and 5B, indicating a fluid flow path 540, show examples of fluid flowing between an external environment 522 and the internal cavity 524 of electronic device 100 through the port 504 defined by a housing 502 and through barometric vent 500. In some examples, the membrane 528 can be a porous membrane including a variety of pores 532. In some examples, the permeability of at least one of the first permeability or the second permeability are less than about 50 SCCM per cm\hat{ }2 of membrane active area. In some examples, the membrane 528 can be made of a sponge-like material. In some examples, a sponge-like material can include any compressible porous material that can change its fluid permeability based on a level of compression and a volume of its pores when in the level of compression. In some examples, when compressed, the sponge-like material can have a reduced pore volume and a corresponding lower level of permeability.

In some examples, the actuator 518 can selectively actuate the barometric vent 500 using at least one of electromagnetism, temperature dependency, or electrostatic actuation. In some examples, the barometric vent 500 can also include an environmental sensor 520 electrically coupled to the actuator 518. In some examples, when the environmental sensor 520 senses a change in the external environment 522 at a predetermined threshold, the environmental sensor 520 sends a trigger to a controller for the actuator 518 to actuate the barometric vent 500 between the open and closed positions, shown in FIGS. 5A and 5B, respectively. In the open position shown in FIG. 5A, the membrane 528 is expanded with a lower density compared to the density of the compressed membrane 528 in the closed position. As two of the terminal ends of the membrane 528 come closer together in the closed position shown in FIG. 5B, the membrane 528 is compressed, the density of the membrane 528 increases, the fluid flowing through the fluid path 540 is reduced or restricted. In some examples, the pores 532 can be at least partially interconnected to form fluid pathways through the membrane 528 in the open, less-compressed position. When the membrane 528 is compressed in the closed position, the pores 532 can likewise be compressed to close or reduce the number of interconnected fluid pathways through the pores 532. This compression results in less fluid flow through the membrane 538 and pores 532 thereof, or a higher pressure differential required to push fluid through the membrane 528.

In some examples, the actuator 518 can selectively compress or release compression on the membrane 528 by applying pressure on at least one of the two terminal ends of the membrane 528. Although FIGS. 5A and 5B shows an example of the actuator 518 selectively compressing or releasing compression on the membrane 528 by applying pressure to the top terminal end of the membrane 528, in other examples, the actuator 518 can selectively compress or release compression on the membrane 528 by applying pressure to the bottom terminal end of the membrane 528. The actuator 518 can apply the pressure directly on the membrane 528, or indirectly, for example by applying pressure to one or more low-flow membranes 530 positioned adjacent to two terminal ends of the membrane 528.

In some examples, the barometric vent 500 can be configured such that the actuator 518 is configured to be triggered to actuate the barometric vent 500 in response to at least one of a signal from the environmental sensor 520 or an input from a user who can be permitted to manually actuate the barometric vent 500 when an undesirable environment is anticipated. For example, if the user plans to walk in the rain with the electronic device 100 or plans to take the electronic device 100 into a swimming pool or other body of water, the user may choose to change the position of the barometric vent 500 manually, such as by proactively closing the barometric vent 500 without waiting for the environmental sensor 520 to sense the undesirable environment 522 and actuate the barometric vent 500 automatically. In some examples, the user may be able to override the actuation of barometric vent 500 despite the environmental sensor 520 sensing an acceptable or undesirable external environment 522 to open or close the barometric vent 500 according to the user's discretion.

Any of the features, components, and/or parts, including the arrangements and configurations thereof shown in FIG. 5A-5B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 5A-5B.

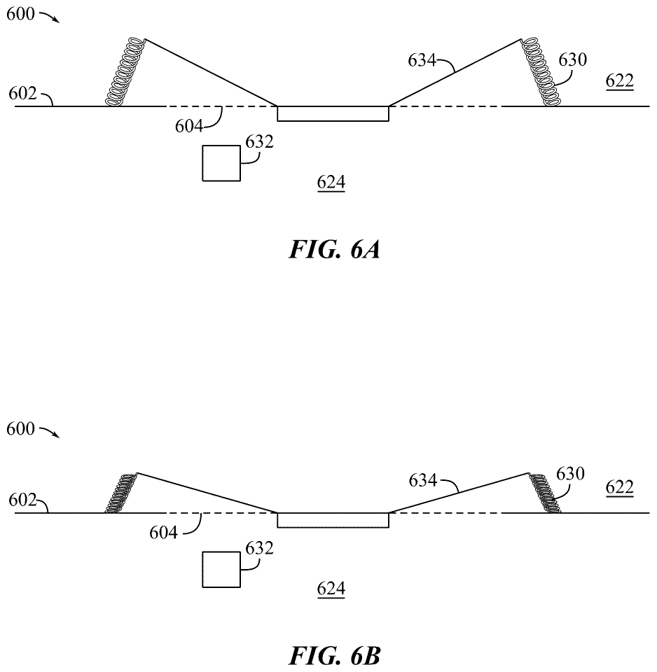

FIG. 6A-6B show cross-sectional views of an example of a barometric vent 600 of the electronic device 100 in an open position and a closed position, respectively. In some examples, the barometric vent 600 includes a joint 630 and a seal 634. In some examples, the joint 630 can include a valve. In some examples, the joint 630 can increase or decrease in size in response to a change in the electronic device's 100 external environment 622 (for example in response to a change of the external environment's temperature or pressure) causing the barometric vent 600 to transition between an open position, shown in FIG. 6A, and a closed position, shown in FIG. 6B. When the barometric vent is in an open position, shown in FIG. 6A, fluid can flow with little resistance between the external environment 622 and the internal cavity 624 defined by a housing 602 of the electronic device 100 and through a port 604. In some examples, when the actuator 618 actuates the barometric vent 600 to be in the closed position, shown in FIG. 6B, the seal 634 covers the port 604 to protect internal components 632 of the electronic device 100 disposed in the internal volume 624.

Any of the features, components, and/or parts, including the arrangements and configurations thereof shown in FIG. 6A-6B can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 6A-6B.

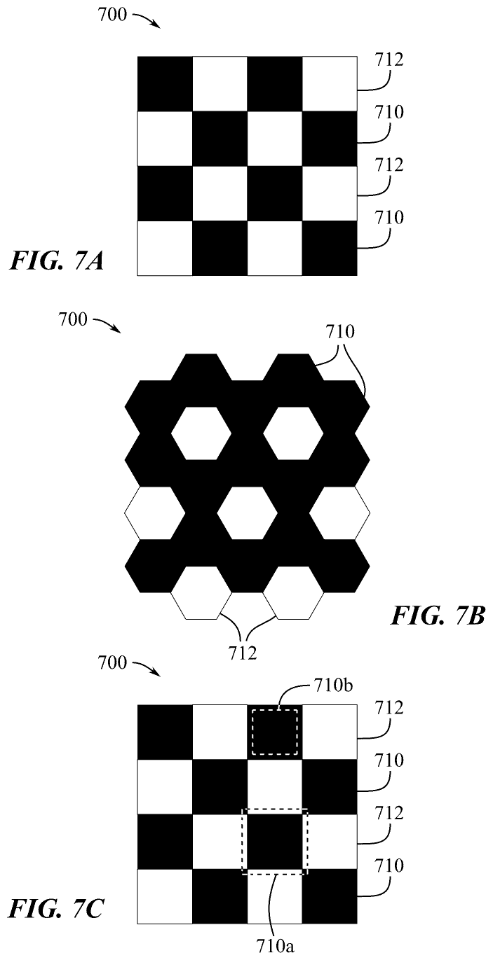

FIG. 7A shows a top view of an example of a membrane 700. The membrane 700 can be similar to membrane layers 206 and 208 shown in the side-views of FIG. 2A-2B or the membrane layers 306, 308 shown in FIGS. 3A and 3B. In some examples, the membrane 700 can include a first membrane section 710 and a second membrane section 712. In some examples, the first membrane section 710 can be a low-flow section (e.g., similar to the low flow membrane 316 shown in FIGS. 3A and 3B and the low flow membrane portion 210 shown in FIGS. 2A and 2B) and the second membrane section 712 can be a high-flow section (e.g., similar to the high flow membrane 314 in FIGS. 3A and 3B or the high flow membrane portion 214 in FIGS. 2A and 2B). Each of the membrane sections 710, 712 can be arranged and shaped as shown in FIG. 7A. In the illustrated example, the various sections 710, 712 having different permeabilities can be arranged as squares or rectangles in a checkerboard pattern. Any number of sections can be arranged an any number of patterns to achieve a desired overall permeability of the membrane 700. Also, while only two sections 710, 712 are shown and repeated in the pattern of the membrane 700 in FIG. 7A, examples of the membrane 700 can also include three, four, five, or more different sections of unique permeability arranged in a pattern to form the single membrane 700.

FIG. 7B shows a top view of another example of the membrane 700 including polygonal (e.g., hexagonal) sections 710, 712 arranged in a honeycomb pattern. The same features of these sections 710, 712, including other examples and arrangements described above with reference to the example shown in FIG. 7A, can apply to the polygonal sections 710, 712 of the membrane 700 shown in FIG. 7B. The number, position, permeability, and size of the sections 710, 712 can vary.

In both examples shown in FIGS. 7A and 7B, the membrane 700 can be one of multiple membranes places adjacent to one another and moved relative to one another to change an overall permeability of a barometric vent including the multiple membranes. In one example, the membrane 700 form either FIG. 7A or 7B can be adjacent another membrane having various sections with various permeabilities that when brought closer together, contacting each other, or moved apart from one another, alters the overall permeability of fluid or gas passing through the multiple membranes.

FIG. 7C shows a top view of the membrane 700 similar to the membrane 700 shown in FIG. 7A, with various sections 710, 712 of different permeabilities arranged together. An adjacent membrane (not shown as a whole) can include sections similar to those sections 710, 712 of membrane 700 but positioned to correspond as shown by sections 710a, 710b. These sections 710a, 710b of one or more adjacent membranes can be larger than the sections 710, 712 of the membrane 700 shown, for examples the larger membrane section 710a relative to the section 710, or smaller as illustrated by the adjacent membrane section 710b. In such examples, when the multiple membranes are brought together, the adjacent sections (e.g., 710, 710a or 710, 710b) can have boundaries that overlap. This can be similar to the overlapping of various membrane sections shown in FIGS. 3A and 3B where the membrane section 316 overlaps the membrane sections 310 and 312. In another example, adjacent sections 710, 712 of adjacent membranes can be similar in size, shape, and position to align such that the boundaries thereof align as shown in the examples of FIGS. 2A and 2B where the various sections 216, 212, and 214 are aligned when brought together.

Any of the features, components, and/or parts, including the arrangements and configurations thereof shown in FIG. 7A-7C can be included, either alone or in any combination, in any of the other examples of devices, features, components, and parts shown in the other figures described herein. Likewise, any of the features, components, and/or parts, including the arrangements and configurations thereof shown and described with reference to the other figures can be included, either alone or in any combination, in the example of the devices, features, components, and parts shown in FIG. 7A-7C.

To the extent applicable to the present technology, gathering and use of data available from various sources can be used to improve the delivery to users of invitational content or any other content that may be of interest to them. The present disclosure contemplates that in some instances, this gathered data may include personal information data that uniquely identifies or can be used to contact or locate a specific person. Such personal information data can include demographic data, location-based data, telephone numbers, email addresses, X® (formerly TWITTER®) ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of advertisement delivery services, the present technology can be configured to allow users to select to “opt in” or “opt out” of participation in the collection of personal information data during registration for services or anytime thereafter. In another example, users can select not to provide mood-associated data for targeted content delivery services. In yet another example, users can select to limit the length of time mood-associated data is maintained or entirely prohibit the development of a baseline mood profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, content can be selected and delivered to users by inferring preferences based on non-personal information data or a bare minimum amount of personal information, such as the content being requested by the device associated with a user, other non-personal information available to the content delivery services, or publicly available information.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An electronic device, comprising:
a housing defining an internal cavity and a port, the internal cavity in fluid communication with an external environment through the port;
an environmental sensor in the internal cavity; and
a barometric vent disposed at the port between the environmental sensor and the housing, the barometric vent comprising:
a first membrane comprising:
a first portion having a first permeability; and
a second portion having a second permeability higher than the first permeability;
a second membrane comprising:
a third portion having a third permeability higher than the first permeability; and
a fourth portion aligned with the second portion, the fourth portion having a fourth permeability less than the second permeability; and
an actuator electrically coupled to the sensor and configured to selectively actuate the barometric vent between an open position and a closed position in response to a signal from the environmental sensor;
wherein:
the open position includes the first membrane separated from the second membrane; and
the closed position includes the fourth portion in contact with the first membrane.

2. The electronic device of claim 1, wherein the actuator comprises an electromagnet.

3. The electronic device of claim 1, wherein the actuator comprises a shape memory alloy.

4. The electronic device of claim 1, wherein the actuator is configured to selectively actuate the barometric vent via electrostatic actuation.

5. The electronic device of claim 1, wherein the actuator comprises a piezoelectric actuator.

6. The electronic device of claim 1, further comprising a retention spring coupling the actuator to at least one of the first membrane or the second membrane.

7. The electronic device of claim 1, wherein the first permeability and the fourth permeability are less than about 50 SCCM per cm\hat{ }2 of a membrane active area.

8. The electronic device of claim 1, wherein the environmental sensor comprises at least one of a moisture sensor, a pressure sensor, or a temperature sensor.

9. The electronic device of claim 1, wherein the actuator is configured to be selectively triggered by a user.

10. A barometric vent for a portable electronic device, the barometric vent, comprising:
a first membrane layer, the first membrane layer comprising:
a first low-flow membrane having a first permeability; and
a high-flow portion, the high-flow portion comprising at least one of a hole defined by the first low-flow membrane or a first high-flow membrane having a second permeability; and
a second membrane layer adjacent the first membrane layer, the second membrane layer comprising:
a second high-flow membrane having a third permeability; and
a second low-flow membrane having a fourth permeability, the second low-flow membrane positioned in line with the high-flow portion; and
an actuator configured to selectively position the first membrane layer relative to the second membrane layer to change a flow rate of the barometric vent.

11. The barometric vent of claim 10, wherein:
the first low-flow membrane is positioned in line with the second high-flow membrane; and
at least one of the hole or the first high-flow membrane is positioned in line with the second low-flow membrane.

12. The barometric vent of claim 11, further comprising a third membrane layer, the third membrane layer comprising a third high-flow membrane and a third low-flow membrane, wherein the third low-flow membrane is positioned in line with the second high-flow membrane.

13. The barometric vent of claim 10, wherein:
the high-flow portion comprises a first high-flow portion and a second high-flow portion;
the first membrane layer comprises:
a first membrane section including the first high-flow portion, and the second low-flow membrane; and
a second membrane section adjacent to the first membrane section, the second membrane section including the second high-flow portion, and the second low-flow membrane; and
the first high-flow portion and the second high-flow portion are both in line with the second low-flow membrane of the second membrane layer.

14. The barometric vent of claim 10, wherein the actuator is configured to selectively actuate a position of at least one of the first membrane layer or the second membrane layer using at least one of electromagnetism, temperature dependency, piezoelectric actuation, or electrostatics.

15. A barometric vent, comprising:
a membrane having a first volume and a second volume; and
an actuator configured to switch the membrane between the first volume and the second volume;
wherein the first volume corresponds to a first permeability and the second volume corresponds to a second permeability different than the first permeability.

16. The barometric vent of claim 15, wherein the second permeability is less than about 50 SCCM per cm\hat{ }2 of a membrane active area.

17. The barometric vent of claim 15, wherein the membrane further comprises a sponge-like material.

18. The barometric vent of claim 15, wherein the actuator is configured to selectively actuate the barometric vent using at least one of electromagnetism, temperature dependency, or electrostatic actuation.

19. The barometric vent of claim 15, further comprising an environmental sensor electrically coupled to the actuator.

20. The barometric vent of claim 19, wherein the actuator is configured to be triggered to switch the membrane between the first volume and the second volume by at least one of the environmental sensor or a user.
